(19) United States
(12) Patent Application Publication
(10) Pub. No.: US 2013/0068954 A1
(43) Pub. Date: Mar. 21, 2013

(54) NON-PLANAR ENERGY TRANSDUCERS, METHODS FOR UTILIZING THE SAME, AND METHODS FOR MANUFACTURING THE SAME

(71) Applicant: Isaac Wing-Tak CHAN, Hsinchu City (TW)

(72) Inventor: Isaac Wing-Tak CHAN, Hsinchu City (TW)

(73) Assignee: INDUSTRIAL TECHNOLOGY RESEARCH INSTITUTE, Hsinchu (TW)

(21) Appl. No.: 13/327,739

(22) Filed: Dec. 15, 2011

(30) Foreign Application Priority Data
Sep. 16, 2011 (TW) TW100133353

(51) Int. Cl. G01T 1/24; H01L 31/0224; H01L 31/0352

(52) U.S. Cl. 250/370.01; 257/458; 257/431; 438/98; 257/E31.032; 257/E31.124

(57) ABSTRACT

Disclosed is a non-planar energy transducer, including a substrate and a switching device disposed thereon. An elastomer having a periodic structure is disposed on the switching device. A bottom electrode is conformally disposed on the elastomer to electrically connect to the switching device. An energy conversion layer is conformally disposed on the bottom electrode, and a top electrode is conformally disposed on the energy conversion layer, wherein the top electrode connects to a positive voltage or a negative voltage.

### CROSS REFERENCE TO RELATED APPLICATIONS

This application claims priority of Taiwan Patent Application No. 100133353, filed on Sep. 16, 2011, the entirety of which is incorporated by reference herein.

### BACKGROUND OF THE DISCLOSURE

1. Field of the Disclosure

The disclosure relates to a non-planar energy transducer, and in particular relates to an elastomer structure thereof.

2. Description of the Related Art

In a conventional X-ray image detector, an X-ray light is firstly transferred to a visible light by a phosphor, and the visible light is then transferred to a current by an optoelectronic converter. The current is then processed by a switching device such as a thin film transistor to obtain an X-ray image. Although the described detector has a flexible structure, the indirect method of forming the current will decrease the resolution of the X-ray image.

Recently, a flat-panel detector (FPD) has been developed to obtain an X-ray image with high resolution. An X-ray conversion layer can be formed on an active array such as TFT array of the FPD, thereby directly transferring an X-ray to a current. Because the FPD is free of additional phosphors and an optoelectronic converter, the processes for preparing the same can be simplified. In addition, the X-ray is directly transferred to the current without being transferred to a visible light, and the current processed by the TFT will be coincident to the incident X-ray intensity. As such, the X-ray image of the FPD has a higher resolution than the indirect current transferred from the visible light firstly transferred from the X-ray. However, the X-ray conversion layer such as an amorphous selenium layer has a thickness of 100 μm to 1000 μm, which is not very flexible and may even be rigid.

Accordingly, the flexible X-ray image detector has low resolution, but the X-ray image detector having high resolution has poor flexibility. A novel X-ray image detector simultaneously having high resolution, high sensitivity, and flexibility is still called-for.

### BRIEF SUMMARY OF THE DISCLOSURE

One embodiment of the disclosure provides a non-planar energy transducer, comprising: a substrate; a switching device disposed on the substrate; an elastomer having a periodic structure disposed on the switching device; a bottom electrode conformally disposed on the elastomer to electrically connect to the switching device; an energy conversion layer conformally disposed on the bottom electrode; and a top electrode conformally disposed on the energy conversion layer, wherein the top electrode connects to a positive voltage or a negative voltage.

One embodiment of the disclosure provides a method for utilizing a non-planar energy transducer, comprising: providing the described non-planar energy transducer, wherein the top electrode is conformally located on a surface of a non-planar object; and applying an energy to travel through the non-planar object and the top electrode, wherein the energy conversion layer transfers the energy to an electron and a hole, and the electron or the hole flows to the switching device through the bottom electrode for forming an electronic signal.

One embodiment of the disclosure provides a method for forming a non-planar energy transducer, comprising: providing a substrate; forming a switching device on the substrate; forming an elastomer having a periodic structure on the switching device; conformally forming a bottom electrode on the elastomer to electrically connect to the switching device; conformally forming an energy conversion layer on the bottom electrode; and conformally forming a top electrode on the energy conversion layer.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIGS. 1 and 4 show non-planar energy transducers in embodiments of the disclosure;

FIG. 2 shows a cross-sectional view along the y-axis direction of the non-planar energy transducer in FIG. 1; and

FIGS. 3A-3D show different cross-sectional shapes of the elastomer in embodiments of the disclosure.

### DETAILED DESCRIPTION OF THE DISCLOSURE

This description is made for the purpose of illustrating the general principles of the disclosure and should not be taken in a limiting sense. The scope of the disclosure is determined by reference to the appended claims.

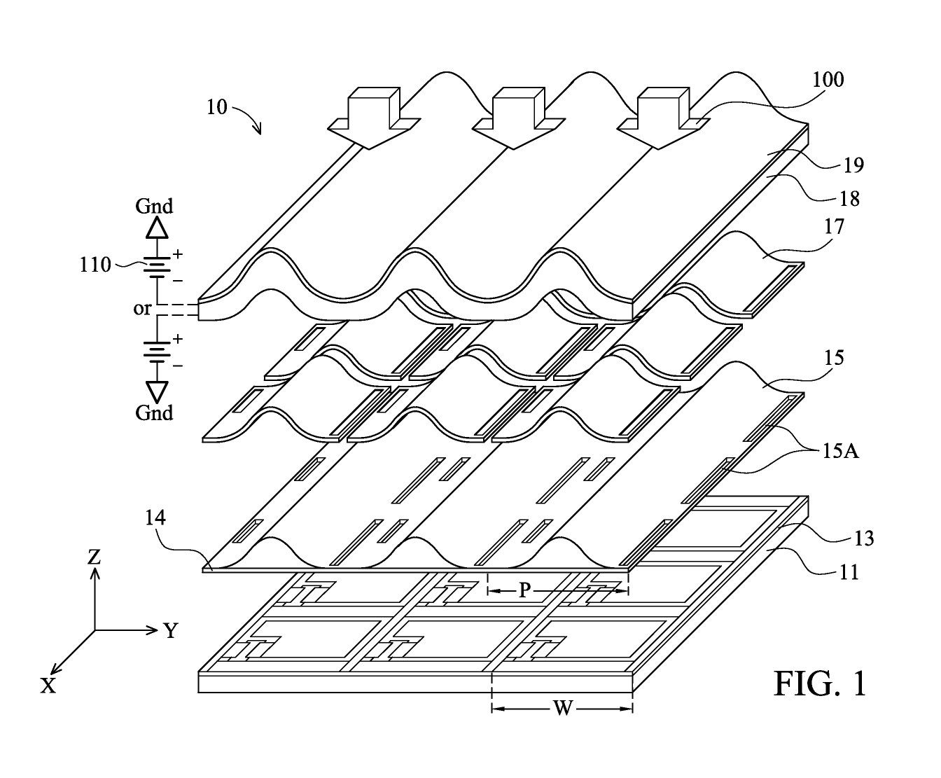

FIG. 1 shows a non-planar energy transducer 10 in one embodiment of the disclosure. First, an array of switching devices 13 is formed on a substrate 11. The substrate 11 can be metal foil such as steel, aluminum, or titanium having a thickness of 20 μm to 300 μm, plastic such as PI, PEN, or PES having a thickness of 15 μm to 200 μm, thin film glass having a thickness of 50 μm to 100 μm, or thin film polysilicon having a thickness of 50 μm to 100 μm. The switching device 13 can be a thin film transistor (TFT), diode, storage capacitor, or combinations thereof. In one embodiment, the switching device 13 further includes an active pixel sensor (APS). In one embodiment, the switching device 13 is the TFT, such as a TFT having a top gate structure, a TFT having a bottom gate structure, a TFT having a dual gate structure, or a TFT having a multi gate structure. The processes of forming the TFT on the substrate can be found in Thin Film Transistors: Materials and Processes, Vol. 1—Amorphous Silicon Thin Film Transistors, edited by Yue Kuo, Kluwer Academic Publishers, USA, 2004, Ch.4, and therefore is omitted here.

An elastomer 15 is then formed on the switching device 13. As shown in FIG. 1, the elastomer 15 has a periodic structure, and the periodic structure has a period P along the y axis. FIG. 1 shows the period P as being substantially similar to the width W of the switching device 13. In one embodiment, the elastomer 15 is composed of a printable silicone, which is periodically printed on the switching device 13 by inkjet printing, screen printing, flexography printing, or gravure printing, thereby forming a silicone pattern. The silicone pattern is then cured by photo curing or thermal curing to complete the elastomer 15 as shown in FIG. 1. In another embodiment, the elastomer 15 is composed of a photosensitive silicone. The photosensitive silicone is formed on the switching device 13 by spin-on coating, dipping, spraying, or the likes, thereby forming a photosensitive silicone layer. The photo sensitive silicone layer is then exposed and developed by a lithography process to complete the elastomer 15. It should be understood that the photomask for exposing the photosensitive silicone layer can be a grey-level photomask to form the wave-shaped elastomer 15 in FIG. 1.

A bottom electrode pattern 17 is then conformally formed on the elastomer 15. Note that the bottom electrode pattern 17 is an array composed of a plurality of separate bottom electrodes, and each of the bottom electrodes corresponds to one switching device 13, respectively. Furthermore, the elastomer 15 does not totally cover the switching device 13, but may have an opening 15A to expose a part of the switching device 13. For example, the opening 15A may expose a drain electrode of the TFT. As such, the bottom electrode may electrically connect to the switching device 13 (e.g. the drain electrode of the TFT) through the opening 15A. The bottom electrode pattern 17 can be a general conductive material such as Mo, W, Ti, or Al, stack structures thereof, or alloys thereof. The bottom electrode pattern 17 can be a general transparent conductive material such as ITO or IZO. For example, the Mo film can be deposited by sputtering, the W film can be deposited by sputtering, the Ti film can be deposited by sputtering, the Al film can be deposited by sputtering or evaporation, the ITO film can be deposited by sputtering, and the IZO film can be deposited by sputtering. After forming a whole layer of the bottom electrode layer, a lithography process and an etching process are processed to form the bottom electrode pattern 17.

An energy conversion layer 18 is then conformally formed on the bottom electrode pattern 17. The energy conversion layer 18 can be a semiconductor material such as amorphous selenium, HgI₂, or PhI₂. The energy conversion layer 18 may have a thickness of 30 μm to 500 μm. For example, the amorphous selenium layer may have a thickness of about 100 μm to 500 μm, the HgI₂ layer may have a thickness of about 30 μm to 150 μm, and the PbI₂ layer may have a thickness of about 30 μm to 150 μm. If the energy conversion layer 18 has an overly thin thickness, the X-ray will not be transferred to electrons and holes. If the energy conversion layer 18 has an overly thick thickness, the flexibility of the non-planar energy transducer 10 will be influenced.

In one embodiment, the energy conversion layer 18 can be a single-layered structure of semiconductor material. In another embodiment, the energy conversion layer 18 can be a multi-layered structure of semiconductor materials, such as P-I-N structure, I-P structure, or I-N structure. For example, when the amorphous selenium is adopted to compose the energy conversion layer 18, which can be an amorphous selenium doped by p-type dopant/amorphous selenium without doping/amorphous selenium doped by n-type dopant (P-I-N) structure, an amorphous selenium without doping/amorphous selenium doped by n-type dopant (I-N) structure, or an amorphous selenium doped by p-type dopant/amorphous selenium without doping (I-P) structure. In other embodiments, a dielectric layer (not shown) or other layered structures can be disposed between the energy conversion layer 18 and the top electrode 19 (described as below), and/or between the energy conversion layer 18 and the bottom electrode pattern 17. Note that the electron current or the current transferred by the energy conversion layer 18 will be conducted to the top electrode 19 and the bottom electrode, respectively, without being influenced by the dielectric layer or other layered structures.

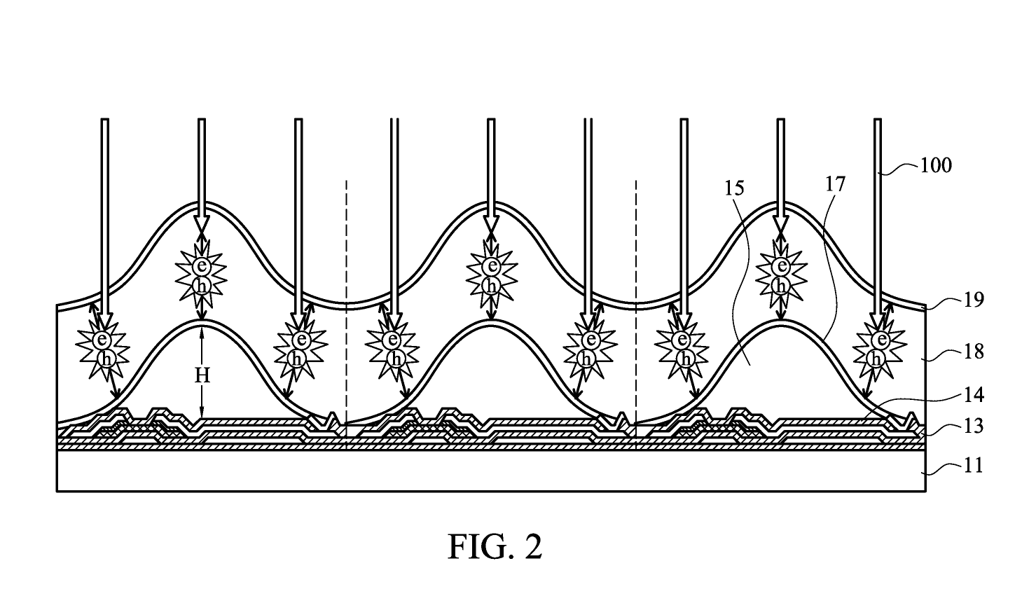

Finally, a whole layer of a top electrode 19 is conformally formed on the energy conversion layer 18. The top electrode 19 is connected to the external voltage 110, such as a positive voltage of about 100V to 5000V or a negative electrode of about −100V to −5000V. When the energy conversion layer 18 is composed of amorphous selenium, the external voltage 110 can be about 1000V to 5000V. When the energy conversion layer 18 is composed of HgI₂, the external voltage 110 can be about 100V to 500V. When the energy conversion layer 18 is composed of PbI₂, the external voltage 110 can be about 100V to 500V. The composition and the formation of the top electrode 19 are similar to that of the bottom electrode, and therefore omitted here. In one embodiment, the top electrode 19 can be formed by a similar material and similar process (without lithography and etching processes) as the bottom electrode pattern 17 to simplify the processes. As such, the description of the non-planar energy transducer 10 is completed, and the cross-sectional view thereof is shown in FIG. 2.

As shown in FIG. 2, the energy 100 traveling through the top electrode 19 and entering the energy conversion layer 18 will be transferred to electrons (e) and holes (h). Because the top electrode 19 in FIG. 2 connects to a positive external voltage (not shown), the electrons (e) flow to the top electrode 19 and the holes (h) flow to the bottom electrode pattern 17, respectively. The flowing holes (h) finally form a current conducted to the switching device 13. In FIG. 2, the current will be conducted to a drain electrode of the TFT to form an electronic signal. In another embodiment, the top electrode 19 connects to a negative external voltage (not shown), the holes (h) flow to the top electrode 19 and the electrons (e) flow to the bottom electrode pattern 17, respectively. The flowing electrons (e) finally form an electron current conducted to the switching device 13. The electron current will be conducted to a drain electrode of the TFT to form an electronic signal. Because the electrons (e) or holes (h) flow toward the bottom electrode pattern 17 in a direction perpendicular to the bottom electrode pattern 17, one bottom electrode corresponding to one TFT only receives the electrons (e) or holes (h) transferred by the energy conversion layer 18 corresponding to same TFT, and does not receives the electrons (e) or holes (h) transferred by the energy conversion layer 18 corresponding to other TFTs. In other words, the non-planar energy transducer 10 has a better image resolution than a conventional flat energy transducer without the elastomer 15 of the disclosure. The electronic signal intensity received by the TFT is the intensity of the energy 100. The image of the energy 100 can be obtained by the electronic signals of the TFT array. In one embodiment, the energy 100 can be heat, electromagnetic wave such as an X-ray, visible light, a γ-ray, sound wave, or pressure.

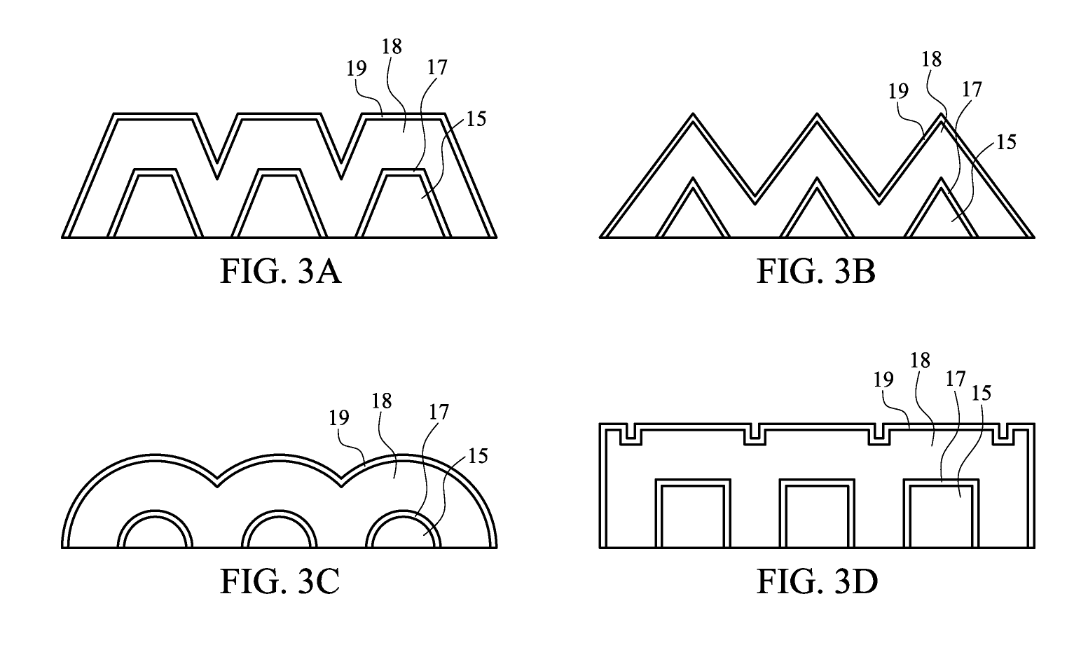

The elastomer 15 in FIG. 2 has a cross-sectional shape of a wave. In other embodiments, the elastomer 15 may have a cross-sectional shape of a trapezoid as shown in FIG. 3A, a triangle as shown in FIG. 3B, a semicircle as shown in FIG. 3C, a square as shown in FIG. 3D, or a rectangle (not shown). In one embodiment, the cross-sectional shape of a trapezoid, a semicircle, a triangle, a square, or a rectangle has round corners. Whatever cross-sectional shape is adopted, the elastomer 15 has a periodic structure, and the bottom electrode pattern 17, the energy conversion layer 18, and the top electrode 19 are all conformally formed on the elastomer 15. The height H of the elastomer 15 is determined by the thickness and the composition of the energy conversion layer 18. In one embodiment, the elastomer 15 has a height of 20 μm to 100 μm. The elastomer 15 having an overly short height H may decrease the flexibility of the non-planar energy transducer 10. The elastomer 15 having an overly long height H may decrease the process reliability of depositing the energy conversion layer 18.

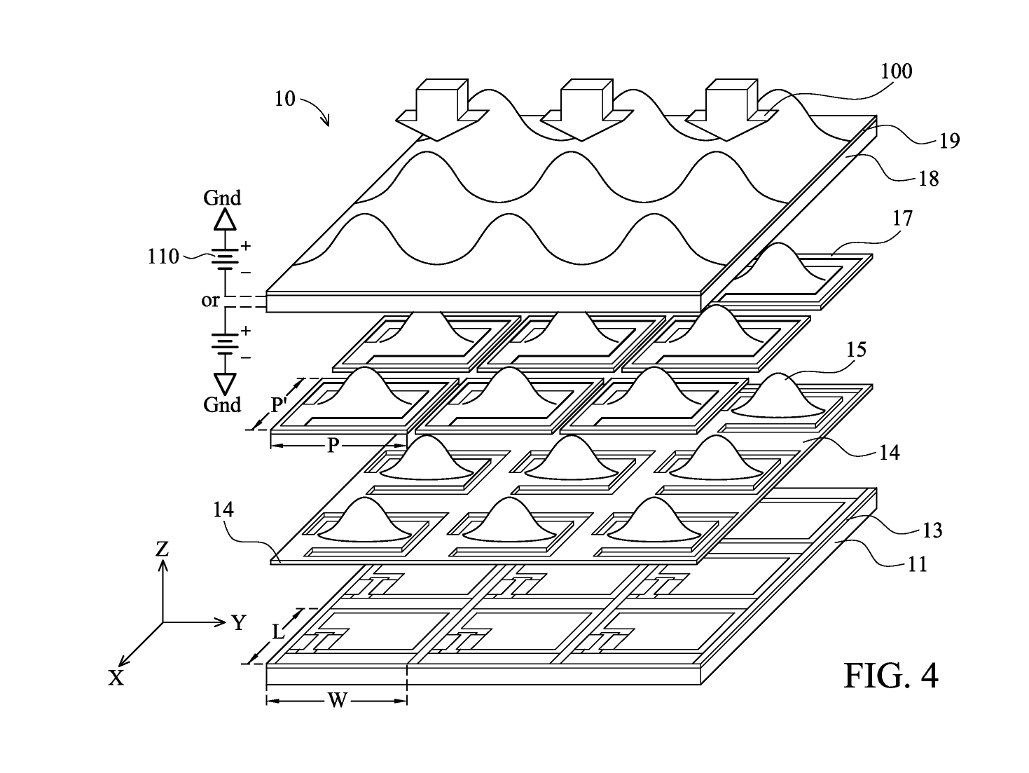

Note that the non-planar energy transducer 10 having the wave-shaped elastomer 15 is flexible along the y-axis direction. In other words, the non-planar energy transducer 10 is a one-dimensional flexible device and not a two-dimensional flexible device. The design of FIG. 4 can be adopted to increase flexible directions of the non-planar energy transducer 10. In FIG. 4, the compositions, the formations, and the factors of the substrate 11, the switching device 13, the elastomer 15, the bottom electrode pattern 17, the energy conversion layer 18, the top electrode 19, the energy 100, and the external voltage 110 are similar to that of the non-planar energy transducer 10 in FIG. 1. The periodic structure of the elastomer 15 in FIG. 4 not only has a period P in the y-axis direction, but also a period P′ in the x-axis direction. The period P is substantially similar to the width W of the switching device 13, and the period P′ is substantially similar to the length L of the switching device 13, respectively. As such, the non-planar energy transducer 10 can be flexible along the x-axis direction, the y-axis direction, or other directions of combinations of the x-axis and the y-axis vectors. In short, the non-planar energy transducer 10 in FIG. 4 is a two-dimensional flexible device.

According to theoretical calculations, if an amorphous selenium layer having a thickness of about 200 nm serving as the energy conversion layer 18 is collocated with an elastomer 15 having a height H of about 20 μm to 50 μm, the flexible radius of the non-planar energy transducer 10 will be less than or equal to 5 cm. Alternatively, if the amorphous selenium layer having a same thickness is not collocated with the elastomer 15, the flexible radius of the non-planar energy transducer will be about 1 m.

In one embodiment, a protection layer 14 can be further disposed between the elastomer 15 and the switching device 13. The protection layer 14 can be made of dielectric material such as organic material, inorganic material, or organic-inorganic composite material. The protection layer 14 composed of the organic material can be formed by vacuum deposition or solution coating. The protection layer 14 composed of the inorganic material can be formed by sputtering, evaporation, or plasma enhanced chemical vapor deposition (PECVD). The protection layer 14 composed of the organic-inorganic composite material can be formed by vacuum deposition or solution coating. In one embodiment, the protection layer 14 is composed of the inorganic material such a silicone nitride, silicon oxide, silicon oxynitride, or stacked structures thereof. Note that the protection layer 14 should be patterned to prevent shielding of the openings 15A. In practice, the top electrode 19 of the non-planar energy transducer 10 is conformally disposed on a surface of a non-planar object (e.g. human body). Thereafter, an energy 100 is applied to travel through the object and the top electrode 19. The energy 100 is transferred to holes (h) and electrons (e) by the energy conversion layer 18. The holes (h) (or electron (e)) flow to the switching device 13 through the bottom electrode to form electronic signals as shown in FIG. 2.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A non-planar energy transducer, comprising:
a substrate;
a switching device disposed on the substrate;
an elastomer having a periodic structure disposed on the switching device;
a bottom electrode conformally disposed on the elastomer to electrically connect to the switching device;
an energy conversion layer conformally disposed on the bottom electrode; and
a top electrode conformally disposed on the energy conversion layer, wherein the top electrode connects to a positive voltage or a negative voltage.

2. The non-planar energy transducer as claimed in claim 1, wherein the substrate comprises a metal foil, plastic, thin film glass, or thin film polysilicon.

3. The non-planar energy transducer as claimed in claim 1, wherein the switching device comprises a thin film transistor, diode, storage capacitor, or combinations thereof.

4. The non-planar energy transducer as claimed in claim 1, wherein the elastomer comprises silicone.

5. The non-planar energy transducer as claimed in claim 1, wherein the periodic structure of the elastomer has a cross-sectional shape of a wave, a trapezoid, a semicircle, a triangle, a square, or a rectangle.

6. The non-planar energy transducer as claimed in claim 5, wherein the cross-sectional shape of the trapezoid, the semicircle, the triangle, the square, or the rectangle has round corners.

7. The non-planar energy transducer as claimed in claim 1, wherein the energy conversion layer is a semiconductor layer having a thickness of 100 μm to 1000 μm.

8. The non-planar energy transducer as claimed in claim 1, wherein the energy conversion layer is a single-layered structure of semiconductor material, or a multi-layered structure of semiconductor materials, wherein the multi-layered structure comprises a P-I-N structure, an I-P structure, or an I-N structure.

9. The non-planar energy transducer as claimed in claim 1, further comprising a dielectric layer between the energy conversion layer and the bottom electrode, and/or between the energy conversion layer and the top electrode.

10. The non-planar energy transducer as claimed in claim 1, further comprising a protection layer between the elastomer and the switching device.

11. The non-planar energy transducer as claimed in claim 1, wherein the periodic structure has a period substantially similar to a width and/or a length of the switching device.

12. A method for utilizing a non-planar energy transducer, comprising:
providing the non-planar energy transducer as claimed in claim 1, wherein the top electrode is conformally located on a surface of a non-planar object; and
applying an energy to travel through the non-planar object and the top electrode,
wherein the energy conversion layer transfers the energy to an electron and a hole, and the electron or the hole flows to the switching device through the bottom electrode for forming an electronic signal.

13. The method as claimed in claim 12, wherein the non-planar object comprises a human body.

14. The method as claimed in claim 12, wherein the energy comprises heat, an electromagnetic wave, a sound wave, or a pressure.

15. The method as claimed in claim 12, wherein the non-planar energy transducer further comprises a protection layer between the switching device and the elastomer.

16. A method for forming a non-planar energy transducer, comprising:
providing a substrate;
forming a switching device on the substrate;
forming an elastomer having a periodic structure on the switching device;
conformally forming a bottom electrode on the elastomer to electrically connect to the switching device;
conformally forming an energy conversion layer on the bottom electrode; and
conformally forming a top electrode on the energy conversion layer.

17. The method as claimed in claim 16, wherein the step of forming the elastomer comprises:
spin-coating a photosensitive silicone layer on the switching device; and
exposing and developing the photosensitive silicone layer to form the elastomer.

18. The method as claimed in claim 16, wherein the step of forming the elastomer comprises:
inkjet printing a silicone pattern on the switching device; and
curing the silicone pattern to form the elastomer.

19. The method as claimed in claim 16, further forming a protection layer between the elastomer and the switching device.

20. The method as claimed in claim 16, wherein the periodic structure has a period substantially similar to a width and/or a length of the switching device.
